(19) United States
(12) Patent Application Publication
(10) Pub. No.: US 2026/0002262 A1
(43) Pub. Date: Jan. 1, 2026

(54) SHOWERHEAD WITH CONTROLLED VAPOR DEPOSITION UNIFORMITY

(71) Applicant: Applied Materials, Inc., Santa Clara, CA (US)

(72) Inventors: Hyman Lam, San Jose, CA (US); Shinjae Hwang, Santa Clara, CA (US); Ziyun Huang, Santa Clara, CA (US); Yun-Tai Yeh, Hsinchu (TW); Vince Kirchhoff, Santa Clara, CA (US); Dien-Yeh Wu, San Jose, CA (US); Chengyu Wen, Santa Clara, CA (US)

(73) Assignee: Applied Materials, Inc., Santa Clara, CA (US)

(21) Appl. No.: 18/755,057

(22) Filed: Jun. 26, 2024

(51) Int. Cl. C23C 16/52; C23C 16/455; H01L 21/66

(52) U.S. Cl. CPC C23C 16/52; C23C 16/45544; C23C 16/45565; H01L 22/12

(57) ABSTRACT

A vapor deposition chamber showerhead faceplate having a thickness and a plurality of zones between a center of the faceplate and the peripheral edge. The faceplate includes a plurality of gas openings, each of the plurality of gas openings comprising an overall length that extends through the thickness of the showerhead faceplate, the overall length defined by an upper part having an upper part length and a lower part having a lower part length, the upper part having a first diameter and the lower part having a second diameter that is less than the first diameter, wherein the lower part length of a first portion of the plurality of gas openings in a first zone is different than the lower part length of a second portion of the plurality of gas openings in a second zone.

### TECHNICAL FIELD

Embodiments of the disclosure generally relate to the field of semiconductor device manufacturing. More particularly, embodiments of the disclosure are directed to showerheads used in the manufacture of semiconductor devices.

### BACKGROUND

The semiconductor processing industry continues to strive for larger production yields while increasing the uniformity of layers deposited on substrates having larger surface areas. As circuit integration increases, the need for greater uniformity and process control of layer thickness rises.

Chemical vapor deposition (CVD) is one of the most common deposition processes employed for depositing layers on substrates. CVD involves control of the substrate temperature and the precursors to produce a desired layer of uniform thickness across substrates that are as large as 300 mm in diameter. Cyclical deposition or atomic layer deposition (ALD) involves sequential delivery of precursor molecules on a substrate surface. In one example, an ALD cycle includes exposing the substrate surface to a first precursor, a first purge gas, a second precursor, and a first purge gas. The first and second precursors react to form a product compound as a layer (or film) on the substrate surface. The cycle is repeated to form the film to a desired thickness. CVD and ALD methods to deposit metal, semiconductor or dielectric films on a substrate such as a semiconductor wafer are performed in a substrate processing chamber. Precursor and/or reactant gases may be flowed through a showerhead having a plurality of gas openings through which the gases flow.

Existing showerheads sometimes lack controlled deposition to provide film thickness uniformity across entire surface of the substrate such as a 300 mm diameter substrate. There is a need to provide improved showerheads used in vapor deposition processes such as CVD and ALD processes that provide deposition of thin films exhibiting controlled thickness uniformity across the surface of the substrate.

### SUMMARY

One or more embodiments of the disclosure are directed to a vapor deposition showerhead configured for use in a substrate processing chamber to deposit films on substrates used to make microelectronic devices. The vapor deposition chamber showerhead comprises a showerhead faceplate comprising a thickness extending from an upper surface to a lower surface, a diameter, a center, an outer peripheral edge, and a plurality of zones across the diameter of the showerhead faceplate including a central zone adjacent to the center, an outer peripheral zone adjacent the outer peripheral edge, and intermediate zones between the central zone and the outer peripheral zone; and a plurality of gas openings, each of the plurality of gas openings comprising an overall length that extends through the thickness of the showerhead faceplate, the overall length defined by an upper part having an upper part length and a lower part having a lower part length, the upper part having a first diameter and the lower part having a second diameter that is less than the first diameter, wherein the lower part length of a first portion of the plurality of gas openings is different than the lower part length of a second portion of the plurality of gas openings.

In another embodiment, a method of method of improving vapor deposition uniformity on a substrate in a substrate processing chamber. The method comprises depositing a film on a substrate in a substrate processing chamber using a vapor deposition process, the substrate processing chamber including a showerhead faceplate comprising a thickness extending from an upper surface to a lower surface, a diameter, a center, a peripheral edge, and a plurality of zones across the diameter of the showerhead faceplate including a central zone adjacent to the center, an outer peripheral zone adjacent the outer peripheral edge, and intermediate zones between the central zone and the outer peripheral zone, the showerhead faceplate further comprising a plurality of gas openings, each of the plurality of gas openings comprising an overall length that extends through the thickness of the showerhead faceplate, the overall length defined by an upper part having an upper part length and a lower part having a lower part length, the upper part having a first diameter and the lower part having a second diameter that is less than the first diameter; measuring a thickness of the film at a plurality of locations across a surface of the substrate; determining a thickness variation across a surface of the substrate; and modifying the lower part length of the showerhead faceplate in at least one of the plurality of zones to reduce the thickness variation across the surface of the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of the present disclosure and are therefore not to be considered limiting of its scope, for the disclosure may admit to other equally effective embodiments.

FIG. 1 illustrates a sectional view of a substrate processing chamber according to one or more embodiments of the disclosure;

FIG. 2 illustrates a bottom view of a showerhead faceplate used in the substrate processing chamber of FIG. 1 according to an exemplary embodiment;

FIG. 3 illustrates a cross-section view of a showerhead faceplate used in the substrate processing chamber of FIG. 1; and

FIG. 4 is a flowchart illustrating a method according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of +2%, +1%, +0.5%, or +0.1%.

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as a metallic material, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a first purge gas, such as argon or nitrogen, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., hydrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. As used herein, the term “thermal process(es)” refers to a deposition technique that does not involve the use of plasma. As used herein, the term “plasma” refers to a composition have ionically charged species and uncharged neutral and radical species.

The embodiments of the disclosure are described by way of the Figures, which illustrate processes and apparatuses in accordance with one or more embodiments of the disclosure. The processes and resulting showerheads shown are merely illustrative of the disclosed processes, and the skilled artisan will recognize that the disclosed processes are not limited to the illustrated embodiments.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

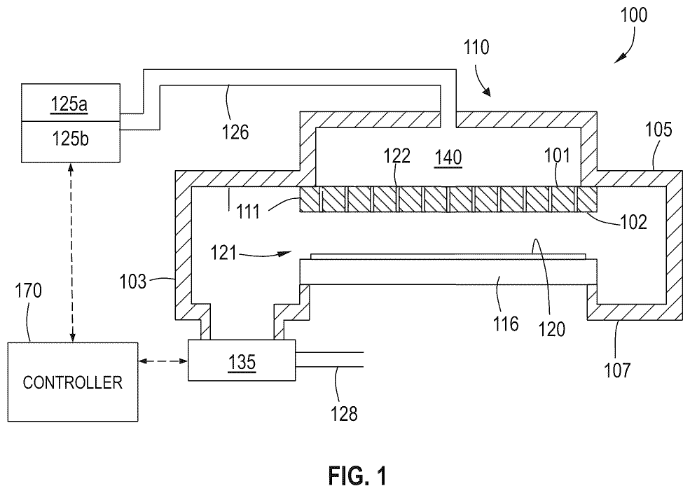

FIG. 1 is a sectional view of a substrate processing chamber 100. The substrate processing chamber 100 has a sidewall 103, a top wall 105, and a bottom wall 107 which enclose a process volume 121. A substrate pedestal 116, which supports a substrate 120, mounts to the bottom wall 107 of the substrate processing chamber 100. In certain embodiments, the substrate pedestal 116 is heated and/or cooled by use of embedded heat transfer fluid lines (not shown), or an embedded thermoelectric device (not shown), to improve the plasma process results on the substrate 120 surface. A vacuum pump 135 controls the pressure within the substrate processing chamber 100, at a pressure in a range of from 0.1 Torr to about 30 Torr, for example from about 0.5 Torr to 25 Torr. A showerhead 110 configured to distribute gases into the process volume 121 comprises a gas distribution plenum 140 connected to a process gas supply 125 and a reactive gas supply 125b via gas supply line 126. While one gas supply line 126 is shown in FIG. 1, more than one gas supply line 126 can be utilized to separately deliver a process gas from the process gas supply 125 and the reactive gas supply 125b. The process gas delivered from the process gas supply 125 and the reactive gas delivered from the reactive gas supply 125b flow through the gas distribution plenum 140 and a plurality of gas openings 122 in a showerhead faceplate 111 of the showerhead 110 to the process volume 121. The process gas according to one or more embodiments comprises a carrier gas such as air, hydrogen, argon or other suitable carrier cases. The reactive gas according to one or more embodiments comprises one or more precursors configured to form a metal, a semiconductor or a dielectric film on the substrate 120. In one or more embodiments, the showerhead 110 is made from a metal or ceramic material (e.g., anodized aluminum or aluminum oxide). An exhaust line 128 is configured to remove reaction byproducts from the substrate processing chamber 100. A controller 170 is configured to control operation of the vacuum pump 135, delivery of the process gas and the reactive gas from the process gas supply 125a and the reactive gas supply 125b. A showerhead faceplate 111 comprises an upper surface 101 and a lower surface 102. A plurality of gas openings 122 extend through the showerhead faceplate 111 from the lower surface 102 to the upper surface 101. A lack of deposition uniformity from gases exiting different zones of the showerhead faceplate 111 can result in an unacceptable variance in the film thickness in different zones of the substrate during a vapor deposition process such as a CVD or an ALD process.

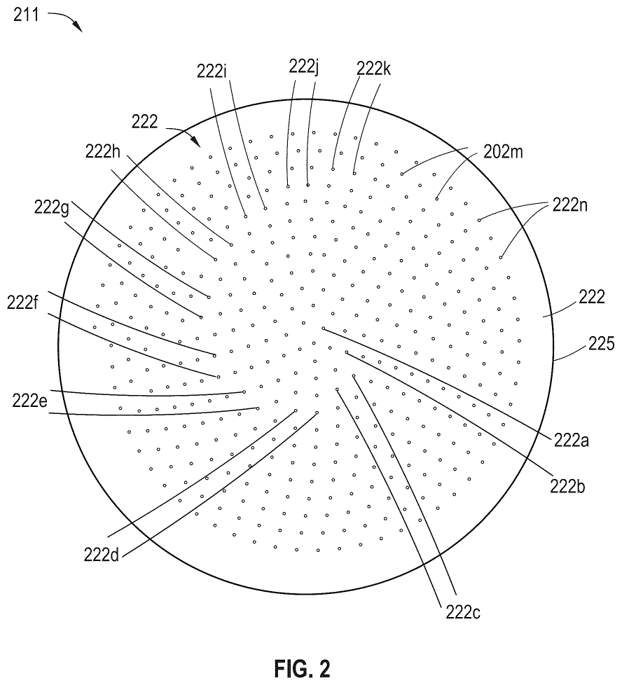

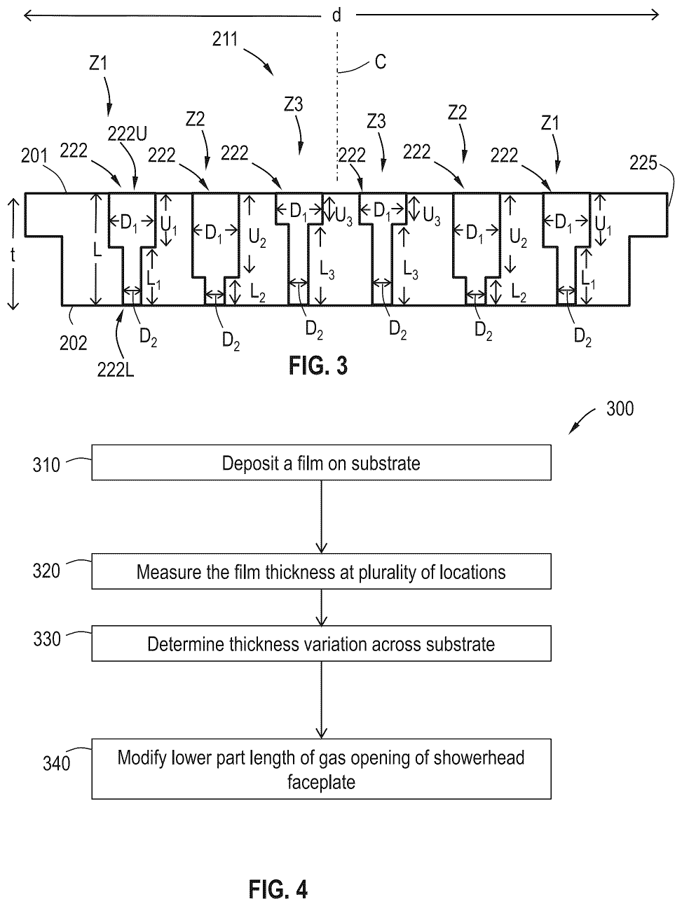

Referring now to FIG. 2, a showerhead faceplate 211 according to a nonlimiting embodiment of the disclosure is shown. The showerhead faceplate 211 comprises a lower surface 202 and a plurality of gas openings 222 that extend through the showerhead faceplate 211. The number of gas openings is dependent on a number of factors, including, but not limited to the spacing of the gas openings 222. In some embodiments there is a range of about 150 and 2000 gas openings 222, or in the range of about 200 to about 1800 gas openings 222, or in the range of about 250 to about 1700 gas openings 222.

Some CVD and ALD processes exhibit precursor dosage effects on film deposition uniformity on a substrate from the center to edge of the wafer. Some embodiments of the disclosure provide a spiral gas distribution gas opening pattern on the showerhead faceplate 211 as shown in FIG. 2, which is configured to provide improved center to edge non-uniformity. However, even with a spiral gas distribution gas opening pattern on the showerhead faceplate 211, improvement is film thickness uniformity is needed. Some embodiments provide different gas delivery zones with different amounts of precursor flow to improve uniformity by adjusting the length of a lower part of the gas openings in the showerhead faceplate 211. In some embodiments, the amount of precursor flow is controlled using stepped gas openings having different length dimensions as described further below.

Still referring to FIG. 2, the gas openings 222 are arranged in a spiral pattern. According to one or more embodiments, a spiral pattern refers to a pattern of gas openings 222 form a curve that is the locus of a point that rotates about a fixed point 212a while continuously increasing its distance from that fixed point 222a. As shown in FIG. 2, the fixed point 222a is the center of the showerhead faceplate 211 and a center gas opening. Moving away from the fixed point 222a towards an outer peripheral edge 225 of the showerhead faceplate 211, there are successive groups of gas openings 222b, 222c, 222d, 222e, 222f, 222g, 222h, 222i, 222j, 222k, 222m, and 222n moving further away from the fixed point 212a (the center gas opening) defining the center of the showerhead faceplate. Each of these groups of gas openings 222a-m define zones of the showerhead faceplate.

As shown from FIG. 2, the gas openings 222 in the spiral pattern including a first group of gas openings 222b that define a central zone surrounding the fixed point 212a, a second group of gas openings 222c that define a second zone further from the fixed point 222a than the first group of openings, a third group of gas openings 222d that define a third zone that is further from the fixed point 212a than the second group of gas openings 222c. There is a fourth group of gas openings 222e that define a fourth zone that is further from the fixed point 212a than the third group of gas openings 222d, a fifth group of gas openings 222f that define a fifth zone that is further from the fixed point 222a than the fourth zone defined by the fourth group of gas openings 222e. A sixth group of gas openings 222g, a seventh group of gas openings 222h, an eighth group of gas openings 222i, a ninth group of gas openings 222j, a tenth group of gas openings 222k, an eleventh group of gas openings 222m and a twelfth group of gas openings 222n respectively define a sixth zone, a seventh zone, an eighth zone, a ninth zone, a tenth zone, an eleventh zone and a twelfth zone on the showerhead faceplate 211, which are respectively further from the fixed point 212a that defines the center of the showerhead faceplate 211. The twelfth zone defined by the twelfth group of gas openings 222n is the zone that is closest to the outer peripheral edge 225. It will be understood that the present disclosure is not limited to a spiral pattern of gas openings 222 as shown in FIG. 2 or any particular number of zones as shown in FIG. 2.

FIG. 3 is a cross-section of a showerhead faceplate 211 that is configured for use in a substrate processing chamber of the type shown in FIG. 1 and which can be used in an ALD process or a CVD process to deposit a film such as a metal film, a dielectric film or a semiconductor film on a substrate surface. While similar reference characters are used for the showerhead faceplate 211 shown in FIG. 2, the gas openings 222 in FIG. 3 are not in a spiral pattern, and fewer zones are shown than the showerhead faceplate 211 shown in FIG. 2. The disclosure is not limited to the number of zones shown or the pattern of gas openings 222 shown in FIG. 3.

The showerhead faceplate 211 in FIG. 3 has a thickness “t” extending from an upper surface 201 to a lower surface 202, a diameter “d”, a center “C”, an outer peripheral edge 225, and a plurality of zones or regions across the diameter “d” of the showerhead faceplate 211 extending between the opposite ends of the showerhead faceplate at the peripheral edge 224. As used herein, region or zone pertains to a selected area of the showerhead faceplate that includes gas openings. In the embodiment shown, there is a central zone labeled as Z3 adjacent to the center “C” of the showerhead faceplate, an outer peripheral zone Z1 adjacent to the outer peripheral edge 225, and at least one intermediate zone, and typically a plurality of intermediate zones Z2 between the central zone Z3 and the outer peripheral zone Z1. The thickness “t” can be 0.5 inches up to about 2 inches, for example 1.5 inches.

The showerhead faceplate 211 further comprises a plurality of gas openings 222, each of the plurality of gas openings 222 comprising an overall length “L” that extends through the thickness of the showerhead faceplate 211, the overall length “L” defined by an upper part 222U having an upper part length “U1” and a lower part 222L having a lower part length “L1”, the upper part having a first diameter “D1” and the lower part having a second diameter “D2” that is less than the first diameter “D1”, wherein the lower part length of a first portion of the plurality of gas openings in a first zone, the outer peripheral zone Z1, is different than the lower part length of a second portion of the plurality of gas openings in a different zone, for example, a second zone, the intermediate zone Z2. In some embodiments, the diameter D1 is in a range of from 0.0126 to 0.0140 inches (0.305 mm to 0.356 mm), and the diameter D2 is in a range of from 0.0120 to 0.126 inches (0.0305 mm to 0.320 mm), with the proviso that D1 is larger than D2. Therefore, when D2 is 0.0126 inches, D1 must be larger than 0.0126 inches, for example 0.0127 to 0.0140 inches.

In an exemplary embodiment shown in FIG. 3, the first zone is the outer peripheral zone Z1 and is shown as having an upper part length U₁ and a lower part length L₁. The second zone is the intermediate zone Z2 between the first zone and the third zone, which is the central zone Z3. The gas openings 222 in the intermediate zone Z2 have an upper part length U₂ that is greater than the upper part length U₁ of the gas openings in the first zone, the outer peripheral zone Z1. This configuration of the gas openings 222 in the respective outer peripheral zone Z1 and the intermediate zone Z2 having a lower part opening length L₁ in the outer peripheral zone Z1 that is greater than the lower part length L₂ in the intermediate zone Z2. In the third zone, which is the central zone Z3 closest to the center of the showerhead faceplate 211, the lower part length L₃ is greater than the lower part length L₁ of the outer peripheral zone Z1 and the lower part length L₂ in the intermediate zone Z2. In the intermediate zone Z3, the upper part length U3 is the shortest of the three zones, with the outer peripheral zone Z1 gas openings 222 having an upper part length U₁ that is greater than the upper part length U₂ of the gas openings 222 in the intermediate zone Z2.

Advantageously, the first portion of the plurality of gas openings in the outer peripheral zone Z1 is configured to produce a different gas flow conductance than a gas flow conductance from the second portion of the plurality of gas openings in the intermediate zone Z2. It was determined that by varying the lower part length, the gas flow conductance through the gas openings 222 can be attenuated by increasing the lower part length having a smaller second diameter D2 than the first diameter of the upper part of the gas opening. Therefore, the gas flow conductance in the central zone Z3 is the lowest across the diameter D of the showerhead faceplate. In addition, the gas flow conductance is the greatest in the intermediate zone Z2 where the lower part length L₂ is the smallest of the lower part lengths. Thus, because L₃ is greater than L₁, which is greater than L₂, the gas flow conductance through gas opening 22 in the central zone Z3 is lower than the gas flow conductance through the gas openings 222 in the outer peripheral zone Z1, which is lower than the gas flow conductance of the gas openings 222 in the intermediate zone Z3.

There is an inverse relationship between the length of the lower part opening which has a smaller diameter than the upper part opening and the gas flow conductance. Increasing the length of the lower part opening in a particular zone will decrease the gas flow conductance in that zone, while decreasing the length of the lower part opening in a particular zone will increase the gas flow conductance in that that zone. Advantageously, by adjusting the length of the narrower lower part length in different zones or regions of the showerhead faceplate 211, the flow conductance across the diameter of the showerhead faceplate the flow conductance can be tailored or mapped out. Mapping can be used to provide showerhead or faceplate that provides improved film thickness uniformity taking into account process variations in different chamber or in different process recipes with different gas flows or different precursors. For example, different zones, such as a central zone, an outer peripheral zone and one or more intermediate zones can have different lower part lengths to adjust and optimize the gas flow conductance that results in improved film uniformity across the diameter D of the substrate.

In some embodiments, the lower part length L₃ of a third portion of the plurality of gas openings 222 in the central zone Z3 (third zone) is different than the lower part length L₁ of the first portion of the plurality of gas openings in the outer peripheral zone Z1 (first zone) and the lower part length of the second portion of the plurality of gas openings 222 in the intermediate zone Z2 (second zone). In one or more embodiments, the lower part length L₁ of the plurality gas openings 222 in the outer peripheral zone Z1 is greater than the lower part length L₃ of the plurality of the gas openings 222 in the central zone Z3. In other embodiments, the lower part length L₃ of the plurality gas openings 222 in the central zone Z3 is greater than the lower part length L₁ of the plurality of gas openings 222 in the outer peripheral zone Z1.

It will be appreciated that the lower part length L₁ of the plurality of gas openings 222 in the outer peripheral zone Z1 and the lower part length of the plurality of gas openings 222 in the central zone Z3 can be obtained from mapped conductance flow data. The mapped conductance flow data can be obtained from modelling or empirically in a chamber. In some embodiments, the lower part length L₁ of the plurality of gas openings 222 in the outer peripheral zone Z1 and the lower part length L₂ of the plurality of gas openings 222 in the central zone Z2 is obtained from mapped conductance flow data, either from modelling data or empirical data

It will be appreciated that a wide variety of showerhead faceplate 211 configurations can be provided according to one or more embodiments, to provide a showerhead faceplate with an optimized flow conductance obtained from mapped conductance flow data. Thee optimized showerhead faceplate 211 can be used in a vapor deposition chamber as shown in FIG. 1.

Referring now to FIG. 3, A method 300 of improving vapor deposition uniformity on a substrate in a substrate processing chamber is shown in the flowchart. The method 300 comprises at 310 depositing a film on a substrate in a substrate processing chamber using a vapor deposition process, the substrate processing chamber including a showerhead faceplate as described herein with respect to FIG. 2 and FIG. 3. The showerhead faceplate comprises a thickness extending from an upper surface to a lower surface, a diameter, a center, a peripheral edge, and a plurality of zones across the diameter of the showerhead faceplate including a central zone adjacent to the center, an outer peripheral zone adjacent the outer peripheral edge, and intermediate zones between the central zone and the outer peripheral zone, the showerhead faceplate further comprising a plurality of gas openings, each of the plurality of gas openings comprising an overall length that extends through the thickness of the showerhead faceplate, the overall length defined by an upper part having an upper part length and a lower part having a lower part length, the upper part having a first diameter and the lower part having a second diameter that is less than the first diameter

At 320, the method includes measuring a thickness of the film at a plurality of locations across a surface of the substrate, and at 330 the method 300 includes determining a thickness variation across a surface of the substrate. The method 300 at 340 includes modifying the lower part length of the showerhead faceplate in at least one of the plurality of zones to reduce the thickness variation across the surface of the substrate.

In embodiments of the method 300, the lower part length of a first portion of the plurality of gas openings is different than the lower part length of a second portion of the plurality of gas openings. The method may further comprise obtaining a gas flow conductance map in the plurality of zones and saving the gas flow conductance map in the plurality of zones. The method may further comprise manufacturing a showerhead faceplate in accordance with the gas flow conductance map so that the lower part length of a first portion of the plurality of gas openings is different than the lower part length of a second portion of the plurality of gas openings.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A vapor deposition chamber showerhead comprising:
a showerhead faceplate comprising a thickness extending from an upper surface to a lower surface, a diameter, a center, an outer peripheral edge, and a plurality of zones across the diameter of the showerhead faceplate including a central zone adjacent to the center, an outer peripheral zone adjacent the outer peripheral edge, and intermediate zones between the central zone and the outer peripheral zone; and
a plurality of gas openings, each of the plurality of gas openings comprising an overall length that extends through the thickness of the showerhead faceplate, the overall length defined by an upper part having an upper part length and a lower part having a lower part length, the upper part having a first diameter and the lower part having a second diameter that is less than the first diameter, wherein the lower part length of a first portion of the plurality of gas openings in a first zone is different than the lower part length of a second portion of the plurality of gas openings in a different zone.

2. The vapor deposition chamber showerhead of claim 1, wherein the first portion of the plurality of gas openings in the first zone is configured to produce a different gas flow conductance than a gas flow conductance from the second portion of the plurality of gas openings in the second zone.

3. The vapor deposition chamber showerhead of claim 1, wherein the gas openings are in a spiral pattern.

4. The vapor deposition chamber showerhead of claim 1, wherein the showerhead faceplate comprises a range of from 150 to 2000 gas openings.

5. The vapor deposition chamber showerhead of claim 1, wherein the lower part length of a third portion of the plurality of gas openings in a third zone is different than the lower part length of the first portion of the plurality of gas openings in the first zone and the lower part length of the second portion of the plurality of gas openings in the second zone.

6. The vapor deposition chamber showerhead of claim 1, wherein the lower part length of the plurality gas openings in the outer peripheral zone is greater than the lower part length of the plurality of gas openings in the central zone.

7. The vapor deposition chamber showerhead of claim 6, wherein the lower part length of the plurality gas openings in the central zone is greater than the lower part length of the plurality of gas openings in the outer peripheral zone.

8. The vapor deposition chamber showerhead of claim 6, wherein the lower part length of the plurality of gas openings in the outer peripheral zone and the lower part length of the plurality of gas openings in the central zone is obtained from mapped conductance flow data.

9. The vapor deposition chamber showerhead of claim 7, wherein the lower part length of the plurality of gas openings in the outer peripheral zone and the lower part length of the plurality of gas openings in the central zone is obtained from mapped conductance flow data.

10. A vapor deposition chamber comprising the vapor deposition chamber showerhead according to claim 1.

11. A method of improving vapor deposition uniformity on a substrate in a substrate processing chamber comprising:
depositing a film on a substrate in a substrate processing chamber using a vapor deposition process, the substrate processing chamber including a showerhead faceplate comprising a thickness extending from an upper surface to a lower surface, a diameter, a center, a peripheral edge, and a plurality of zones across the diameter of the showerhead faceplate including a central zone adjacent to the center, an outer peripheral zone adjacent the outer peripheral edge, and intermediate zones between the central zone and the outer peripheral zone, the showerhead faceplate further comprising a plurality of gas openings, each of the plurality of gas openings comprising an overall length that extends through the thickness of the showerhead faceplate, the overall length defined by an upper part having an upper part length and a lower part having a lower part length, the upper part having a first diameter and the lower part having a second diameter that is less than the first diameter;
measuring a thickness of the film at a plurality of locations across a surface of the substrate;
determining a thickness variation across a surface of the substrate; and
modifying the lower part length of the showerhead faceplate in at least one of the plurality of zones to reduce the thickness variation across the surface of the substrate.

12. The method of claim 11, wherein the lower part length of a first portion of the plurality of gas openings in a first zone is different than the lower part length of a second portion of the plurality of gas openings in a second zone.

13. The method of claim 12, further comprising obtaining a gas flow conductance map in the plurality of zones.

14. The method of claim 13, further comprising saving the gas flow conductance map in the plurality of zones.

15. The method of claim 14, further comprising manufacturing a showerhead faceplate in accordance with the gas flow conductance map so that the lower part length of a first portion of the plurality of gas openings in a first zone is different than the lower part length of a second portion of the plurality of gas openings in a second zone.
